(19) United States
(12) Patent Application Publication
(10) Pub. No.: US 2008/0185041 A1
(43) Pub. Date: Aug. 7, 2008

(54) Method of making a photovoltaic device with antireflective coating containing porous silica and resulting product

(75) Inventors: Pramod K. Sharma, Ann Arbor, MI (US); Thomas J. Taylor, Northville, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 11/701,541

(22) Filed: Feb. 2, 2007

(51) Int. Cl. B05D 5/00; H01L 31/00

(52) U.S. Cl. 136/261; 136/256; 427/240; 427/74

(57) ABSTRACT

A method of making an anti-reflection coating using a sol-gel process, for use in a photovoltaic device or the like. The method may include the following steps in certain example embodiments: forming a polymeric component of silica by mixing glycycloxypropyltrimethoxysilane (or other suitable silane) with one or more of a first solvent, a catalyst, and water; forming a silica sol gel by mixing the polymeric component with a colloidal silica, optionally a second solvent, and at least one organic additive; casting the mixture by spin coating to form a porous silica based layer on a substrate; and curing and/or heat treating the layer. This layer may make up all or only part of an anti-reflection coating.

This invention relates to a method of making an antireflective (AR) coating supported by a glass substrate for use in a photovoltaic device or the like. The AR coating includes, in certain exemplary embodiments, a porous silica, which may be produced using a sol-gel process including certain organic additive(s). These organic additive(s) may include aliphatic and/or cyclic organic compounds.

### BACKGROUND OF THE INVENTION

Glass is desirable for numerous properties and applications, including optical clarity and overall visual appearance. For some example applications, certain optical properties (e.g., light transmission, reflection and/or absorption) are desired to be optimized. For example, in certain example instances, reduction of light reflection from the surface of a glass substrate may be desirable for storefront windows, display cases, photovoltaic devices such as solar cells, picture frames, other types of windows, and so forth.

Photovoltaic devices such as solar cells (and modules therefor) are known in the art. Glass is an integral part of most common commercial photovoltaic modules, including both crystalline and thin film types. A solar cell/module may include, for example, a photoelectric transfer film made up of one or more layers located between a pair of substrates. One or more of the substrates may be of glass, and the photoelectric transfer film (typically semiconductor) is for converting solar energy to electricity. Example solar cells are disclosed in U.S. Pat. Nos. 4,510,344, 4,806,436, 6,506,622, 5,977,477, and JP 07-122764, the disclosures of which are hereby incorporated herein by reference.

Substrate(s) in a solar cell/module are sometimes made of glass. Incoming radiation passes through the incident glass substrate of the solar cell before reaching the active layer(s) (e.g., photoelectric transfer film such as a semiconductor) of the solar cell. Radiation that is reflected by the incident glass substrate does not make its way into the active layer(s) of the solar cell, thereby resulting in a less efficient solar cell. In other words, it would be desirable to decrease the amount of radiation that is reflected by the incident substrate, thereby increasing the amount of radiation that makes its way to the active layer(s) of the solar cell. In particular, the power output of a solar cell or photovoltaic (PV) module may be dependant upon the amount of light, or number of photons, within a specific range of the solar spectrum that pass through the incident glass substrate and reach the photovoltaic semiconductor.

Because the power output of the module may depend upon the amount of light within the solar spectrum that passes through the glass and reaches the PV semiconductor, certain attempts have been made in an attempt to boost overall solar transmission through the glass used in PV modules. One attempt is the use of iron-free or “clear” glass, which may increase the amount of solar light transmission when compared to regular float glass, through absorption minimization.

In certain example embodiments of this invention, an attempt to address the aforesaid problem(s) is made using an antireflective (AR) coating on a glass substrate (the AR coating may be provided on either side of the glass substrate in different embodiments of this invention). An AR coating may increase transmission of light through the substrate, and thus the power of a PV module in certain example embodiments of this invention.

Certain example embodiments of this invention relate, in part, to the formulation and manufacture of AR coatings produced using a sol-gel process, which are based on porous silica containing organic additives, for use in connection with glass intended to be used as a substrate in a photovoltaic device or the like. These porous silica coatings may have high transmittance, thereby improving the efficiency and/or power of the photovoltaic device.

Thus, it will be appreciated that there may exist a need for an improved AR coating, for solar cells or other applications, to reduce reflection off glass and other substrates.

### BRIEF SUMMARY OF EXAMPLE EMBODIMENTS OF THE INVENTION

In certain example embodiments of this invention, there is provided a method of making an anti-reflection coating for use in a photovoltaic device or the like, the method comprising: forming a polymeric component of silica by mixing at least a silane with one or more of a first solvent, a catalyst, and water; forming a sol gel by mixing the polymeric component with a colloidal silica, optionally a second solvent, and at least one organic additive; casting the mixture by spin coating to form a layer on a glass substrate; and curing and/or heat treating the layer, the layer making up at least part of the anti-reflecting coating.

The organic additive(s) used in making the porous silica based layer (e.g., see layer 3a in the figures) are advantageous in that they permit the resulting density of the final layer 3a to be less or decreased. The use of the organic additive(s) results in a lower density for layer 3a (and thus the AR coating), while maintaining reasonable durability for the overall AR coating. These additive(s) allow the materials of the porous silica based layer to react in an unknown manner in order to help the silica of the layer increase coupling between silica particles, which is advantageous. Moreover, it is noted that the organic additive(s) may burn out during heat treatment, so that they need not be in the final pourous silica based layer in certain example embodiments.

In certain exemplary embodiments of this invention, there is provided a method of making an anti-reflection coating using a sol-gel process including: forming a polymeric component of silica by mixing glycycloxypropyltrimethoxysilane with a first solvent, a catalyst, and water; forming a silica sol gel by mixing the polymeric component with a colloidal silica, a second solvent, and the at least one organic additive; casting the mixture by spin coating to form a coating on a substrate; and curing and heat treating the coating.

In certain exemplary embodiments of this invention, there is a solar cell comprising: a photovoltaic layer and at least a glass substrate on a light incident side of the photovoltaic layer; an anti-reflection coating provided on the glass substrate, the anti-reflection coating being located on a light-incident side of the glass substrate; wherein the anti-reflection coating comprises a first layer provided directly on and contacting the glass substrate, the first layer comprising a coating produced using a sol-gel process including at least one organic additive.

In certain exemplary embodiments of this invention, there is an anti-reflection coating provided on a glass substrate comprising a first layer provided directly on and contacting the glass substrate, the first layer comprising a coating produced using a sol-gel process including at least one organic additive.

### BRIEF DESCRIPTION OF THE DRAWINGS

FIG. 1 is a cross sectional view of a coated article including an antireflective (AR) coating made in accordance with an example embodiment of this invention (this coated article of FIG. 1 may be used in connection with a photovoltaic device or in any other suitable application in different embodiments of this invention).

FIG. 2 is a cross sectional view of a photovoltaic device that may use the AR coating of FIG. 1.

FIG. 3 shows optical spectra of silica coatings containing polyvinylpyrrolidone made in accordance with example embodiments of this invention.

FIG. 4 shows optical spectra of silica coatings containing 1-methyl 2-pyrrolidone made in accordance with example embodiments of this invention.

FIG. 5 shows optical spectra of silica coatings containing 2,4 pentanedione made in accordance with example embodiments of this invention and shows an optical spectra of a porous silica coating prepared without an organic additive.

FIG. 6 shows optical spectra of silica coatings containing triethanolamine made in accordance with example embodiments of this invention.

FIG. 7 shows optical spectra of silica coatings containing ethyl acrylate made in accordance with example embodiments of this invention.

FIG. 8 shows optical spectra of silica coatings containing N,N-dimethylacrylamide made in accordance with example embodiments of this invention.

### DETAILED DESCRIPTION OF EXEMPLARY EMBODIMENTS OF THE INVENTION

Referring now more particularly to the accompanying drawings in which like reference numerals indicate like parts throughout the several views.

This invention relates to antireflective (AR) coatings that may be provided for in coated articles used in devices such as photovoltaic devices, storefront windows, display cases, picture frames, other types of windows, and the like. In certain example embodiments (e.g., in photovoltaic devices), the AR coating may be provided on either the light incident side or the other side of the substrate (e.g., glass substrate).

In certain example embodiments of this invention, an improved anti-reflection (AR) coating is provided on an incident glass substrate of a solar cell or the like. This AR coating may function to reduce reflection of light from the glass substrate, thereby allowing more light within the solar spectrum to pass through the incident glass substrate and reach the photovoltaic semiconductor so that the solar cell can be more efficient. In other example embodiments of this invention, such an AR coating is used in applications other than solar cells, such as in storefront windows, display cases, picture frames, other types of windows, and the like. The glass substrate may be a glass superstrate or any other type of glass substrate in different instances.

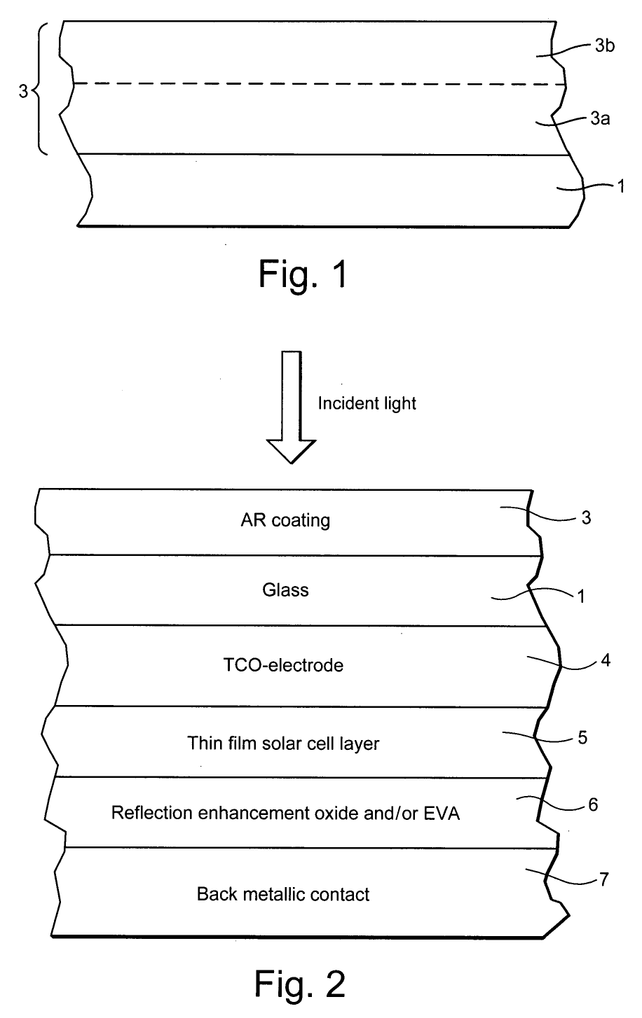

FIG. 1 is a cross sectional view of a coated article according to an example embodiment of this invention. The coated article of FIG. 1 includes a glass substrate 1 and an AR coating 3. The AR coating includes a first layer 3a and an optional overcoat layer 3b.

In the FIG. 1 embodiment, the antireflective coating 3 includes first layer 3a of or including porous silica, which is produced using the sol-gel process including certain organic additives. These organic additives may include aliphatic and cyclic organic compounds. The first layer 3a may be any suitable thickness in certain example embodiments of this invention. However, in certain example embodiments, the first layer 3a of the AR coating 3 has a thickness of approximately 115 nm to 155 nm. Moreover, the refractive index (n) value and/or material composition of the first layer 3a may vary throughout the layer in either a continuous or non-continuous manner in different example embodiments of this invention.

Optionally, the AR coating 3 may also include an overcoat 3b of or including a material such as silicon oxide (e.g., SiO₂), or the like, which may be provided over the first layer 3a in certain example embodiments of this invention as shown in FIG. 1. In certain example embodiments, the overcoat antireflective layer 3b is composed of SiO₂. While silicon oxide is preferred for destructive interference layer 3b in certain example embodiments, it is possible to use other materials for this layer 3b in other example embodiments of this invention. Silicon oxide inclusive layer 3b may be relatively dense in certain example embodiments of this invention; e.g., from about 75-100% hardness, for protective purposes. The overcoat layer 3b may be deposited over layer 3a in any suitable manner. For example, a Si or SiAl target could be sputtered in an oxygen and argon atmosphere to sputter-deposit the silicon oxide inclusive layer 3b. Alternatively, the silicon oxide inclusive layer 3b could be deposited by flame pyrolysis, or any other suitable technique such as spraying, roll coating, printing, via silica precursor sol-gel solution (then drying and curing), coating with a silica dispersion of nano or colloidal particles, vapor phase deposition, and so forth. It is noted that it is possible to form other layer(s) over overcoat layer 3b in certain example instances. It is also possible to form other layer(s) between layers 3a and 3b, and/or between glass substrate 1 and layer 3a, in different example embodiments of this invention.

It is noted that layer 3a and/or 3b may be doped with other materials such as titanium, aluminum, nitrogen or the like.

In certain example embodiments of this invention, high transmission low-iron glass may be used for glass substrate 1 in order to further increase the transmission of radiation (e.g., photons) to the active layer of the solar cell or the like. For example and without limitation, the glass substrate 1 may be of any of the glasses described in any of U.S. patent application Ser. Nos. 11/049,292 and/or 11/122,218, the disclosures of which are hereby incorporated herein by reference. Furthermore, additional suitable glasses include, for example (i.e., and without limitation): standard clear glass; and/or low-iron glass, such as Guardian's ExtraClear, UltraWhite, or Solar. No matter the composition of the glass substrate, certain embodiments of anti-reflective coatings produced in accordance with the present invention may increase transmission of light to the active semiconductor film of the photovoltaic device.

Certain glasses for glass substrate 1 (which or may not be patterned in different instances) according to example embodiments of this invention utilize soda-lime-silica flat glass as their base composition/glass. In addition to base composition/glass, a colorant portion may be provided in order to achieve a glass that is fairly clear in color and/or has a high visible transmission. An exemplary soda-lime-silica base glass according to certain embodiments of this invention, on a weight percentage basis, includes the following basic ingredients: SiO₂, 67-75% by weight; Na₂O, 10-20% by weight; CaO, 5-15% by weight; MgO, 0-7% by weight; Al₂O₃, 0-5% by weight; K₂O, 0-5% by weight; Li₂O, 0-1.5% by weight; and BaO, 0-1%, by weight.

Other minor ingredients, including various conventional refining aids, such as SO₃, carbon, and the like may also be included in the base glass. In certain embodiments, for example, glass herein may be made from batch raw materials silica sand, soda ash, dolomite, limestone, with the use of sulfate salts such as salt cake (Na₂SO₄) and/or Epsom salt (MgSO₄×7H₂O) and/or gypsum (e.g., about a 1:1 combination of any) as refining agents. In certain example embodiments, soda-lime-silica based glasses herein include by weight from about 10-15% Na₂O and from about 6-12% CaO, by weight.

In addition to the base glass above, in making glass according to certain example embodiments of the instant invention the glass batch includes materials (including colorants and/or oxidizers) which cause the resulting glass to be fairly neutral in color (slightly yellow in certain example embodiments, indicated by a positive b* value) and/or have a high visible light transmission. These materials may either be present in the raw materials (e.g., small amounts of iron), or may be added to the base glass materials in the batch (e.g., cerium, erbium and/or the like). In certain example embodiments of this invention, the resulting glass has visible transmission of at least 75%, more preferably at least 80%, even more preferably of at least 85%, and most preferably of at least about 90% (Lt D65). In certain example non-limiting instances, such high transmissions may be achieved at a reference glass thickness of about 3 to 4 mm In certain embodiments of this invention, in addition to the base glass, the glass and/or glass batch comprises or consists essentially of materials as set forth in Table 2 below (in terms of weight percentage of the total-glass composition):

TABLE 2
Example Additional Materials In Glass

| Ingredient | General (Wt. %) | More Preferred | Most Preferred |
|---|---|---|---|
| total iron | 0.001–0.06% | 0.005–0.04% | 0.01–0.03% |
| (expressed as | | | |
| Fe₂O₃): | | | |
| cerium oxide: | 0–0.30% | 0.01–0.12% | 0.01–0.07% |
| TiO₂ | 0–1.0% | 0.005–0.1% | 0.01–0.04% |
| Erbium oxide: | 0.05 to 0.5% | 0.1 to 0.5% | 0.1 to 0.35% |

In certain example embodiments, the total iron content of the glass is more preferably from 0.01 to 0.06%, more preferably from 0.01 to 0.04%, and most preferably from 0.01 to 0.03%. In certain example embodiments of this invention, the colorant portion is substantially free of other colorants (other than potentially trace amounts). However, it should be appreciated that amounts of other materials (e.g., refining aids, melting aids, colorants and/or impurities) may be present in the glass in certain other embodiments of this invention without taking away from the purpose(s) and/or goal(s) of the instant invention. For instance, in certain example embodiments of this invention, the glass composition is substantially free of, or free of, one, two, three, four or all of: erbium oxide, nickel oxide, cobalt oxide, neodymium oxide, chromium oxide, and selenium. The phrase “substantially free” means no more than 2 ppm and possibly as low as 0 ppm of the element or material. It is noted that while the presence of cerium oxide is preferred in many embodiments of this invention, it is not required in all embodiments and indeed is intentionally omitted in many instances. However, in certain example embodiments of this invention, small amounts of erbium oxide may be added to the glass in the colorant portion (e.g., from about 0.1 to 0.5% erbium oxide).

The total amount of iron present in the glass batch and in the resulting glass, i.e., in the colorant portion thereof, is expressed herein in terms of Fe₂O₃ in accordance with standard practice. This, however, does not imply that all iron is actually in the form of Fe₂O₃ (see discussion above in this regard). Likewise, the amount of iron in the ferrous state (Fe⁺²) is reported herein as FeO, even though all ferrous state iron in the glass batch or glass may not be in the form of FeO. As mentioned above, iron in the ferrous state (Fe²⁺; FeO) is a blue-green colorant, while iron in the ferric state (Fe³⁺) is a yellow-green colorant; and the blue-green colorant of ferrous iron is of particular concern, since as a strong colorant it introduces significant color into the glass which can sometimes be undesirable when seeking to achieve a neutral or clear color.

It is noted that the light-incident surface of the glass substrate 1 may be flat or patterned in different example embodiments of this invention.

FIG. 2 is a cross-sectional view of a photovoltaic device (e.g., solar cell), for converting light to electricity, according to an example embodiment of this invention. The solar cell of FIG. 2 uses the AR coating 3 and glass substrate 1 shown in FIG. 1 in certain example embodiments of this invention. In this example embodiment, the incoming or incident light from the sun or the like is first incident on optional layer 3b of the AR coating 3, passes therethrough and then through layer 3a and through glass substrate 1 and front transparent electrode 4 before reaching the photovoltaic semiconductor (active film) 5 of the solar cell. Note that the solar cell may also include, but does not require, a reflection enhancement oxide and/or EVA film 6, and/or a back metallic contact and/or reflector 7 as shown in example FIG. 2. Other types of photovoltaic devices may of course be used, and the FIG. 2 device is merely provided for purposes of example and understanding. As explained above, the AR coating 3 reduces reflections of the incident light and permits more light to reach the thin film semiconductor film 5 of the photovoltaic device thereby permitting the device to act more efficiently.

While certain of the AR coatings 3 discussed above are used in the context of the photovoltaic devices/modules, this invention is not so limited. AR coatings according to this invention may be used in other applications such as for picture frames, fireplace doors, and the like. Also, other layer(s) may be provided on the glass substrate under the AR coating so that the AR coating is considered on the glass substrate even if other layers are provided therebetween. Also, while the first layer 3a is directly on and contacting the glass substrate 1 in the FIG. 1 embodiment, it is possible to provide other layer(s) between the glass substrate and the first layer in alternative embodiments of this invention.

Set forth below is a description of how AR coating 3 may be made according to certain example non-limiting embodiments of this invention.

Exemplary embodiments of this invention provide a new method to produce a porous silica coating for use as the AR coating 3, with appropriate light transmission and abrasion resistance properties. In certain example embodiments of this invention, the coating solution may be based on two different silica precursors, namely (a) a colloidal silica solution including or consisting essentially of particulate silica in a solvent, and (b) a polymeric solution including or consisting essentially of silica chains.

In making the polymeric silica solution, a silane may be mixed with a catalyst, solvent and water. After agitating, the colloidal silica solution (a) is added to the polymeric silica solution (b), optionally with a solvent. The sol gel coating solution is then deposited on a suitable substrate such as a highly transmissive clear glass substrate. Then, the sol gel coating solution on the glass 1 substrate is cured and/or fired, preferably from about 100 to 750° C., and all subranges therebetween, thereby forming the solid AR coating 3 on the glass substrate 1. The final thickness of the AR coating 3 may, though not necessarily, be approximately a quarter wave thickness in certain example embodiments of this invention. It has been found that an AR coating made in such a manner may have adequate durability, thereby overcoming at least some of the aforesaid mechanical/abrasion resistance problems in approaches of the prior art.

In an exemplary embodiment, the sol-gel process used in forming coating 3 may comprise: forming a polymeric component of silica by mixing glycycloxypropyltrimethoxysilane with a first solvent, a catalyst, and water; forming a silica sol gel by mixing the polymeric component with a colloidal silica, a second solvent, and at least one organic additive; casting the mixture by spin coating to form a coating on the glass substrate; and curing and heat treating the coating. Suitable solvents may include, for example, n-propanol, isopropanol, other well-known alcohols (e.g., ethanol), and other well-known organic solvents (e.g., toluene). Suitable catalysts may include, for example, well-known acids, such as hydrochloric acid, sulfuric acid, etc. The colloidal silica may comprise, for example, silica and methyl ethyl ketone. The curing may occur at a temperature between 100 and 150° C. for up to 2 minutes, and the heat treating may occur at a temperature between 600 and 750° C. for up to 5 minutes. Shorter and longer times with higher and lower temperatures are contemplated within exemplary embodiments of the present invention.

In exemplary embodiments of this invention, several organic additives have been used in sol-gel processing of porous silica. The additives, either alone or in combination, may, for example, comprise 0.01 to 50% by weight of the silica sol gel, and all subranges therebetween; 5 to 40% by weight of the silica sol gel, and all subranges therebetween; 10 to 30% by weight of the silica sol gel, and all subranges therebetween; and/or 15 to 25% by weight of the silica sol gel, and all subranges therebetween.

The additives may be aliphatic and/or cyclic organic compounds with one or more of the following functionalities: keto group (e.g., acetyl acetone); pyrrolidone (e.g., polyvinyl pyrrolidone, 1-methyl 2-pyrrolidone); acrylamide (e.g., N—N, dimethylacrylamide); or acrylate (e.g., ethyl acrylate).

The organic additive(s) used in making the porous silica based layer 3a are advantageous in that they permit the final porous silica based layer 3a to be less dense. As visible transmission goes up, density drops. The use of the organic additive(s) results in a lower density for layer 3a (and thus coating 3 which may be up solely of layer 3a, or optionally layer 3a and other layer(s) such as 3b), while keeping reasonable durability for the overall AR coating. Moreover, it is noted that the organic additive(s) may burn out during heat treatment, so that they need not be in the final layer 3a. These additive(s) allow the materials of the layer 3a to react in an unknown manner in order to help the silica of layer 3a increase coupling between silica particles, which is of course advantageous.

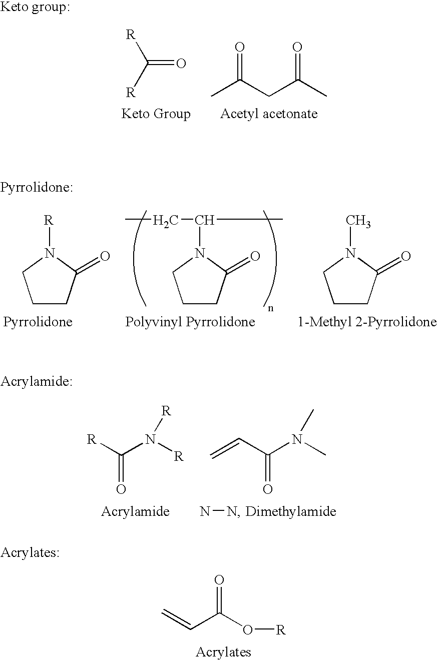

The silicon ion in the sol of acidic medium carries slightly positive charge, and the alkoxide ligands (OR═R, where R can be CₙH₂ₙ₋₁) can carry a negative charge. It may enhance the reaction kinetics producing a good leaving group. Therefore, the following example species may be generated in the acidic medium:

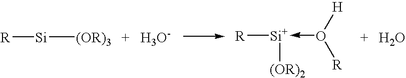

This may enhance the hydrolysis and retard the condensation which gives a liner chain of inorganic polymer. The Si—O—Si network that may lead to the porosity in the final product of the coating may be dependent on the hydrolysis and condensation of the sol gel processing. The additives are generally used to control the kinetics of the reaction, which in turn may influence the packing density, microstructure and optical properties of the coatings. A silicon ion carries a positive charge in acidic conditions, therefore, it may be attacked by any of the negative species in the specified additive, such as, for example:

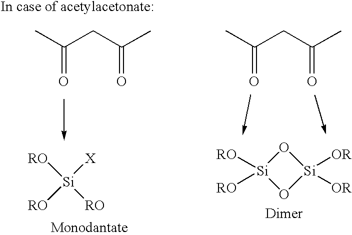

In case of amides:

Amide may be stabilized by delocalization of the nitrogen lone pair electron through orbital overlapping with carbonyl group in resonance term

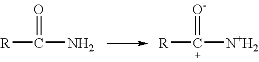

The protonated amide may have high energy because the electron withdrawing carbonyl group may inductively destabilize the neighboring positive charge, i.e., the positively charged silicon ions may form complex ions during the sol formation.

In case of pyrrolidone

The cyclic ring of pyrrolidone may have an electron withdrawing carbonyl group, which forms complex with positively charged ions in the sol formation. This may also be valid for ethyl acrylates.

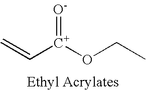

Several examples were prepared. The thicknesses of these coatings range from 115 nm to 155 nm in certain example instances. These Examples are provided for purposes of example only.

### EXAMPLE #1

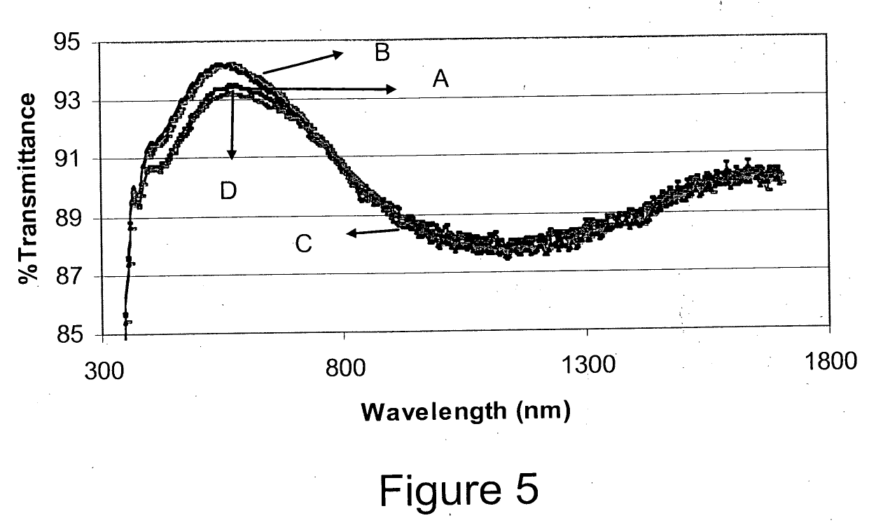

The silica sol was prepared as follows. A polymeric component of silica was prepared by using 64% wt of n-propanol, 24% wt of Glycycloxylpropyltrimethoxysilane (Glymo), 7% wt of water and 5% wt of hydrochloric acid. These ingredients were used and mixed for 24 hrs. The coating solution was prepared by using 21% wt of polymeric solution, 7% wt colloidal silica in methyl ethyl ketone supplied by Nissan Chemicals Inc, and 72% wt n-propanol. This was stirred for 2 hrs to give silica sol. The silica coating was fabricated using spin coating method with 1000 rpm for 18 secs. The coating was cured at 130° C. for 1 minute, then heat treated in furnace at 625° C. for 3 and a half minutes. The optical spectra of this coating is given in FIG. 5 and increase in % transmission and power is shown in Table 3. It is noted that other silane(s) may be used instead of or in addition to Glymo.

### EXAMPLE #2

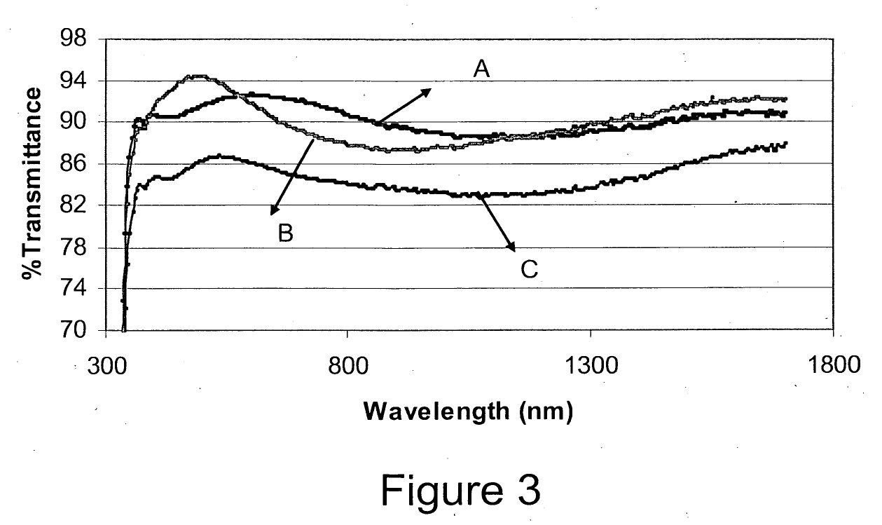

The 10% Wt of polyvinylpyrrolidone was mixed with 90% Wt of silica sol and stirred for 5 minutes. The coating method and heat treatment were the same as mentioned in the example #1. The optical spectra of this coating is given in FIG. 3 and increase in % transmission and power is shown in Table 3.

### EXAMPLE #3

The example #3 is the same as example #2 except the polyvinylpyrrolidone and silica sol were taken in 20:80 percent weight ratio respectively. The optical spectra of this coating is given in FIG. 3 and increase in % transmission and power is shown in Table 3.

### EXAMPLE #4

The example #4 is the same as example #2 except the polyvinylpyrrolidone and silica sol were taken in 30:70 percent weight ratio respectively. The optical spectra of this coating is given in FIG. 3 and increase in % transmission and power is shown in Table 3.

### EXAMPLE #5

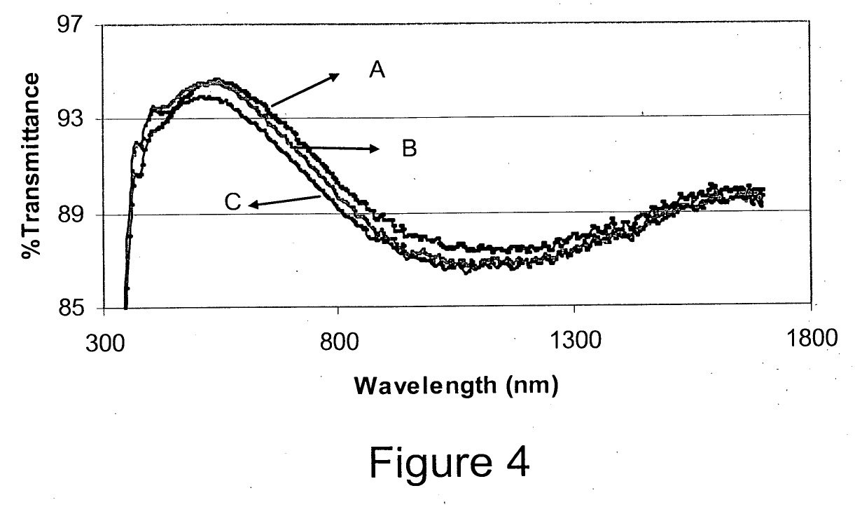

The example #5 is the same as example #2 except the polyvinylpyrrolidone was replaced by 1-methyl 2-pyrrolidone. The optical spectra of this coating is given in FIG. 4 and increase in % transmission and power is shown in Table 3.

### EXAMPLE #6

The example #6 is the same as example #5 except the 1-methyl 2-pyrrolidone and silica sol were taken in 20:80 percent weight ratio respectively. The optical spectra of this coating is given in FIG. 4 and increase in % transmission and power is shown in Table 3.

### EXAMPLE #7

The example #7 is the same as example #5 except the 1-methyl 2-pyrrolidone and silica sol were taken in 30:70 percent weight ratio respectively. The optical spectra of this coating is given in FIG. 4 and increase in % transmission and power is shown in Table 3.

### EXAMPLE #8

The example #8 is the same as example #2 except the polyvinylpyrrolidone was replaced by 2,4 pentanedione. The optical spectra of this coating is given in FIG. 5 and increase in % transmission and power is shown in Table 3.

### EXAMPLE #9

The example #9 is the same as example #8 except the 2,4 pentanedione and silica sol were taken in 20:80 percent weight ratio respectively. The optical spectra of this coating is given in FIG. 5 and increase in % transmission and power is shown in Table 3.

### EXAMPLE #10

The example #10 is the same as example #8 except the 2,4 pentanedione and silica sol were taken in 30:70 percent weight ratio respectively. The optical spectra of this coating is given in FIG. 5 and increase in % transmission and power is shown in Table 3.

### EXAMPLE #11

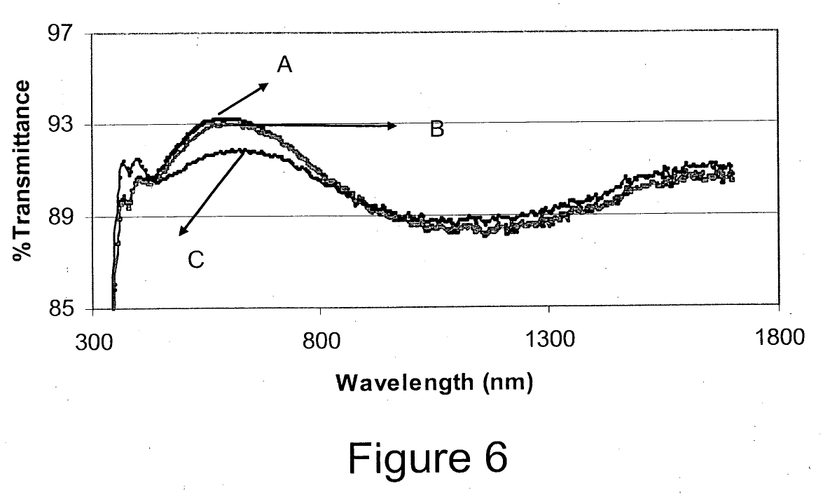

The example #11 is the same as example #2 except the polyvinylpyrrolidone was replaced by triethanolamine. The optical spectra of this coating is given in FIG. 6 and increase in % transmission and power is shown in Table 3.

### EXAMPLE #12

The example #12 is the same as example #11 except the triethanolamine and silica sol were taken in 20:80 percent weight ratio respectively. The optical spectra of this coating is given in FIG. 6 and increase in % transmission and power is shown in Table 3.

### EXAMPLE #13

The example #13 is the same as example #11 except the triethanolamine and silica sol were taken in 30:70 percent weight ratio respectively. The optical spectra of this coating is given in FIG. 6 and increase in % transmission and power is shown in Table 3.

### EXAMPLE #14

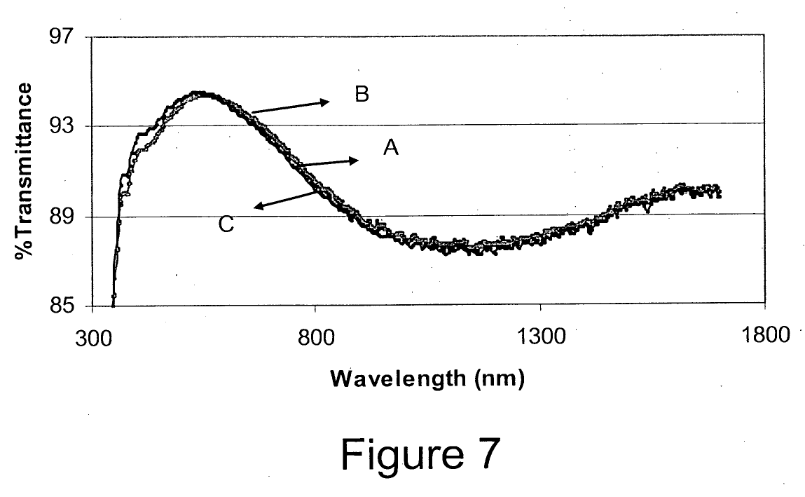

The example #14 is the same as example #2 except the polyvinylpyrrolidone was replaced by ethyl acrylate. The optical spectra of this coating is given in FIG. 7 and increase in % transmission and power is shown in Table 3.

### EXAMPLE #15

The example #15 is the same as example #14 except the ethyl acrylate and silica sol were taken in 20:80 percent weight ratio respectively. The optical spectra of this coating is given in FIG. 7 and increase in % transmission and power is shown in table 1.

### EXAMPLE #16

The example #16 is the same as example #15 except the ethyl acrylate and silica sol were taken in 30:70 percent weight ratio respectively. The optical spectra of this coating is given in FIG. 7 and increase in % transmission and power is shown in table 1.

### EXAMPLE #17

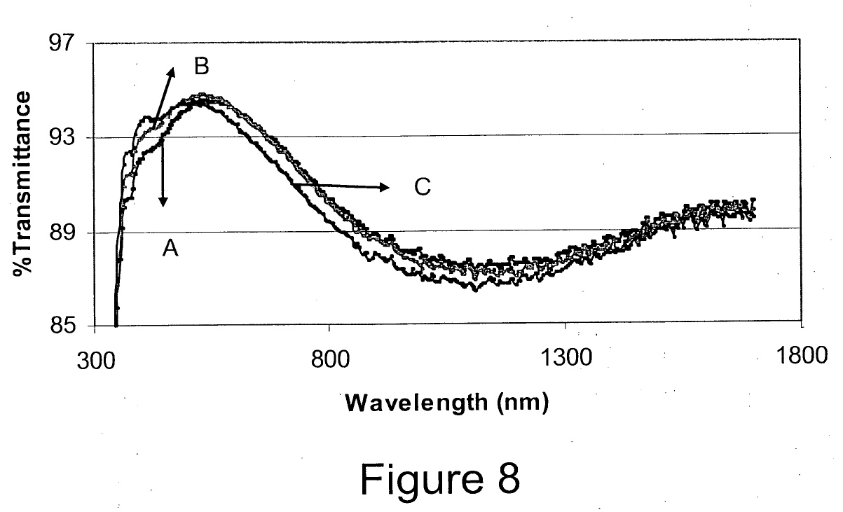

The example #17 is the same as example #2 except the polyvinylpyrrolidone was replaced by N,N-dimethylacrylamide. The optical spectra of this coating is given in FIG. 8 and increase in % transmission and power is shown in Table 3.

### EXAMPLE #18

The example #18 is the same as example #17 except the N,N-dimethylacrylamide and silica sol were taken in 16:84 percent weight ratio, respectively. The optical spectra of this coating is given in FIG. 8 and increase in % transmission and power is shown in Table 3.

### EXAMPLE #19

The example #19 is the same as example #18 except the N,N-dimethylacrylamide and silica sol were taken in 30:70 percent weight ratio respectively. The optical spectra of this coating is given in FIG. 8 and increase in % transmission and power is shown in Table 3.

TABLE 3
AR Coatings derived from porous silica and additives

| | | | | Increase in |
|---|---|---|---|---|
| Example | | Silica sol | Increase | % power |
| No. | Additive (% Wt) | (% Wt) | in % T | (W/m²) |
| 1 | None | 100 | 2.3 | 2.7 |
| 2 | 10% Wt | 90 | 2.2 | 2.4 |
| | Polyvinylpyrrolidone | | | |
| 3 | 20% Wt | 80 | 1.3 | 1.4 |
| | Polyvinylpyrrolidone | | | |
| 4 | 30% Wt | 70 | −3.9 | −4.8 |
| | Polyvinylpyrrolidone | | | |
| 5 | 10% Wt | 90 | 2.6 | 3.3 |
| | 1-Methyl-2Pyrrolidone | | | |
| 6 | 20% Wt | 80 | 2.3 | 3.0 |
| | 1-Methyl-2Pyrrolidone | | | |
| 7 | 30% Wt | 70 | 1.9 | 2.4 |
| | 1-Methyl-2Pyrrolidone | | | |
| 8 | 10% Wt 2,4 Pentanedione | 90 | 2.3 | 2.7 |
| 9 | 20% Wt 2,4 Pentanedione | 80 | 2.5 | 3 |
| 10 | 30% Wt 2,4 Pentanedione | 70 | 2.5 | 3 |
| 11 | 10% Wt Triethanolamine | 90 | 2.4 | 2.6 |
| 12 | 20% Wt Triethanolamine | 80 | 2.3 | 2.5 |
| 13 | 30% Wt Triethanolamine | 70 | 2.1 | 1.9 |
| 14 | 10% Wt Ethyl acrylate | 90 | 2.6 | 3.2 |
| 15 | 20% Wt Ethyl acrylate | 80 | 2.6 | 3.3 |
| 16 | 30% Wt Ethyl acrylate | 70 | 2.5 | 3.2 |
| 17 | 10% Wt | 90 | 2.5 | 3.2 |
| | N-N-Dimethylacrylamide | | | |
| 18 | 16% Wt | 84 | 2.6 | 3.3 |
| | N-N-Dimethylacrylamide | | | |
| 19 | 30% Wt | 70 | 2.1 | 2.3 |
| | N-N-Dimethylacrylamide | | | |

For each of the examples, the % increase in transmission was measured by UV-spectrophotometer from 300 nm to 2500 nm using a PerkinElmer 900. The % increase in transmission is in comparison to glass without an AR coating. Data obtained from the UV-spectrophotometer scanned from 300 to 1200 nm for the coating with substrate and only substrate to generate a theoretical % increase in power. As transmission increases, power should increase. The glass substrate used was Guardian's Extraclear, a low iron glass specifically designed to decrease transmission loss.

FIGS. 3-8 show the relative increase in transmittance of coating glass substrate with an AR coating. FIG. 3 shows optical spectra of silica coatings: A corresponds to Example #1; B corresponds to Example #2 containing polyvinylpyrrolidone; and C corresponds to Example #3 containing polyvinylpyrrolidone. FIG. 4 shows optical spectra of silica coatings containing 1-methyl 2-pyrrolidone: A corresponds to Example #5; B corresponds to Example #6; and C corresponds to Example #7. FIG. 5 shows optical spectra of silica coatings containing 2,4 pentanedione: A corresponds to Example #8; B corresponds to Example #9; and C corresponds to Example #10. In addition, FIG. 5 shows an optical spectra of a porous silica coating prepared without an organic additive (Example #1); it is labeled D. FIG. 6 shows optical spectra of silica coatings containing triethanolamine: A corresponds to Example #11; B corresponds to Example #12; and C corresponds to Example #13. FIG. 7 shows optical spectra of silica coatings containing ethyl acrylate: A corresponds to Example #14; B corresponds to Example #15; and C corresponds to Example #16. FIG. 8 shows optical spectra of silica coatings containing N,N-dimethylacrylamide: A corresponds to Example #17; B corresponds to Example #18; and C corresponds to Example #19. These layers correspond to porous silica based layer 3a of coating 3 in certain example embodiments of this invention. Optionally other layer or layers (e.g., see 3b) may be provided over layer 3a in certain instances.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A method of making an anti-reflection coating for use in a photovoltaic device, the method comprising:
forming a polymeric component of silica by mixing at least glycycloxypropyltrimethoxysilane with at least a first solvent, a catalyst, and water;
forming a silica sol gel by mixing the polymeric component with a colloidal silica, a second solvent, and at least one organic additive;
casting the mixture by spin coating to form a layer on a glass substrate; and
curing and heat treating the layer, and using the layer in at least part of an antireflective coating in the photovoltaic device.

2. The method of claim 1, wherein the curing occurs at a temperature between 100 and 150° C. and has a duration of up to 2 minutes.

3. The method of claim 1, wherein the heat treating occurs at a temperature between 600 and 750° C. and has a duration of up to 5 minutes.

4. The method of claim 1, wherein the first solvent comprises n-propanol.

5. The method of claim 1, wherein the second solvent comprises n-propanol.

6. The method of claim 1, wherein the catalyst comprises an acid.

7. The method of claim 6, wherein the acid comprises hydrochloric acid.

8. The method of claim 1, wherein the colloidal silica comprises methyl ethyl ketone.

9. The method of claim 1, wherein the silica sol gel comprises more than one organic additive.

10. The method of claim 1, wherein the at least one organic additive comprises an organic compound having at least one aliphatic or cyclic organic compounds selected from the group consisting of: keto group; pyrrolidone;
acrylamide; and acrylate.

11. The method of claim 1, wherein the at least one organic additive comprises an organic compound selected from the group consisting of: acetyl acetone;
polyvinyl pyrrolidone; 1-methyl 2-pyrrolidone; N—N, dimethylacrylamide; ethyl acrylate; triethanolamine; and 2,4 pentanedione.

12. The method of claim 1, wherein the at least one organic additive makes up from about 5 to 40% by weight of the silica sol gel.

13. The method of claim 1, wherein the at least one organic additive makes up from about 10 to 30% by weight of the silica sol gel.

14. The method of claim 1, wherein the at least one organic additive makes up from about 15 to 25% by weight of the silica sol gel.

15. The method of claim 1, wherein the at least one organic additive comprises acetyl acetone.

16. The method of claim 1, wherein the silica sol gel comprises 10 to 30% acetyl acetone by weight.

17. The method of claim 1, wherein the at least one organic additive comprises polyvinyl pyrrolidone.

18. The method of claim 1, wherein the silica sol gel comprises 10 to 30% polyvinyl pyrrolidone by weight.

19. The method of claim 1, wherein the at least one organic additive comprises 1-methyl 2-pyrrolidone.

20. The method of claim 1, wherein the at least one organic additive comprises N—N, dimethylacrylamide.

21. The method of claim 1, wherein the at least one organic additive comprises ethyl acrylate.

22. The method of claim 1, wherein the at least one organic additive comprises 2,4 pentanedione.

23. The method of claim 1, wherein the at least one organic additive comprises triethanolamine.

24. A solar cell comprising the antireflection coating made according to claim 1.

25. A method of making an anti-reflection coating, the method comprising:
forming a polymeric component of silica by mixing at least a silane with one or more of a first solvent, a catalyst, and water;
forming a sol gel by mixing the polymeric component with a colloidal silica, optionally a second solvent, and at least one organic additive;
casting the mixture by spin coating to form a layer on a glass substrate; and
curing and/or heat treating the layer, the layer making up at least part of the anti-reflection coating.

26. The method of claim 25, wherein the at least one organic additive comprises one or more of: acetyl acetone; polyvinyl pyrrolidone; 1-methyl 2-pyrrolidone; N—N, dimethylacrylamide; ethyl acrylate; triethanolamine; 2,4 pentanedione; acetyl acetone; polyvinyl pyrrolidone; 1-methyl 2-pyrrolidone; N—N, dimethylacrylamide; ethyl acrylate; triethanolamine; and 2,4 pentanedione.

27. A photovoltaic device comprising:
a photovoltaic film, and at least a glass substrate on a light incident side of the photovoltaic film;
an anti-reflection coating provided on the glass substrate;
wherein the anti-reflection coating comprises at least a layer provided directly on and contacting the glass substrate, the layer produced using a sol-gel process including at least one organic additive.

28. The photovoltaic device of claim 27, wherein the glass substrate comprises a soda-lime-silica glass including the following ingredients: SiO₂, 67-75% by weight; Na₂O, 10-20% by weight; CaO, 5-15% by weight; MgO, 0-7% by weight; Al₂O₃, 0-5% by weight; K₂O, 0-5% by weight; Li₂O, 0-1.5% by weight; and BaO, 0-1%, by weight.

29. The photovoltaic device of claim 27, wherein the anti-reflection coating further comprises an overcoat layer comprising an oxide of silicon provided directly on and contacting the layer.
